(19) United States
(12) Patent Application Publication
(10) Pub. No.: US 2023/0268319 A1
(43) Pub. Date: Aug. 24, 2023

(54) STACKING SEMICONDUCTOR DEVICES BY BONDING FRONT SURFACES OF DIFFERENT DIES TO EACH OTHER

(71) Applicant: ADVANCED MICRO DEVICES, INC., SANTA CLARA, CA (US)

(72) Inventors: RAHUL AGARWAL, LIVERMORE, CA (US); RAJA SWAMINATHAN, AUSTIN, TX (US); JOHN WUU, FORT COLLINS, CO (US)

(21) Appl. No.: 18/046,519

(22) Filed: Oct. 14, 2022

Related U.S. Application Data
(60) Provisional application No. 63/255,934, filed on Oct. 14, 2021.

(51) Int. Cl. H01L 25/065; H01L 23/48; H01L 23/00; H01L 23/522; H01L 21/768; H01L 21/56

(52) U.S. Cl. CPC H01L 25/0657; H01L 23/481; H01L 24/16; H01L 24/08; H01L 23/5226; H01L 21/76898; H01L 24/80; H01L 21/561; H01L 21/568; H01L 2224/16225; H01L 2224/08145; H01L 2224/80895; H01L 2224/80896; H01L 2225/06568

(57) ABSTRACT

A semiconductor assembly includes a first die having a front side metallization layer. The semiconductor assembly also includes a second side having a front side metallization layer that is bonded to the front side metallization layer of the first die.

### BACKGROUND

Conventionally, when stacking dies to form a three-dimensional integrated circuit (3DIC), a back side of a first die is coupled to a front side of a second die, to stack the second die on top of the first die. The back side of the first die does not typically include metallization layers. Instead, the metallization layers of the first die are near a front surface of the first die. The front side of the second die also includes metallization layers. When stacked in a back to front manner, through-silicon vias in the first die are used to couple the front side metallization layers of the first die to the front side metallization layers of the second die. Density of the through-silicon vias in the first die limits a number of interconnections between the first die and the second die.

### BRIEF DESCRIPTION OF THE DRAWINGS

FIG. 1 shows a cross-section of a conventional semiconductor assembly including a first die and a second die according to some implementations.

FIG. 2 is a cross-section of a semiconductor assembly where a metallization layer of a first die is bonded to a metallization layer of a second die according to some implementations.

FIG. 3 shows multiple dies included on a wafer according to some implementations.

FIG. 4 shows dicing of a wafer into multiple dies according to some implementations.

FIG. 5 shows application of a carrier wafer to a back side of first dies diced from the wafer according to some implementations.

FIG. 6 shows application of a gap fill material between the first dies while the first dies are bonded to the carrier wafer according to some implementations.

FIG. 7 shows bonding of a front side metallization layer of a second die to a front side metallization layer of a first die according to some implementations.

FIG. 8 shows application of additional gap fill material between the second dies according to some implementations.

FIG. 9 shows the first carrier wafer bonded to back sides of the first dies and a second carrier wafer bonded to back sides of the second dies according to some implementations.

FIG. 10 shows removal of the first carrier wafer is removed from the back sides of the first dies according to some implementations.

FIG. 11 shows formation of one or more back side metallization layers on the back side of a first die according to some implementations.

FIG. 12 shows solder bumps coupled to portions of a back side metallization layer of a first die according to some implementations.

FIG. 13 shows a carrier wafer bonded to a front side of one or more first dies according to some implementations.

FIG. 14 shows application of a gap fill material between the first dies with the carrier wafer bonded to the front side of the first dies according to some implementations.

FIG. 15 shows the carrier wafer removed from the front side of the first dies and bonded to the back side of the first dies according to some implementations.

FIG. 16 shows an example where an interconnect die is coupled to a first die and to another first die according to some implementations.

FIG. 17 is a cross-sectional diagram of an example integrated circuit device including a semiconductor assembly having a front side metallization layer of a first die bonded to a front side metallization layer of a second die according to some implementations.

FIG. 18 is an example computing device according to some implementations.

FIG. 19 is a flow chart illustrating an example method for manufacturing a semiconductor assembly with a second die bonded to a first die according to some implementations.

### DETAILED DESCRIPTION

As semiconductor technologies further advance, stacked semiconductor devices (e.g., three dimensional integrated circuits (3DICs)), have emerged as an effective alternative to further reduce the physical size of semiconductor devices. In a stacked semiconductor device, a first die is in a first level, with a second die stacked atop the first die to form a second level. This stacking of dies atop one another further reduces a form factor of the semiconductor device.

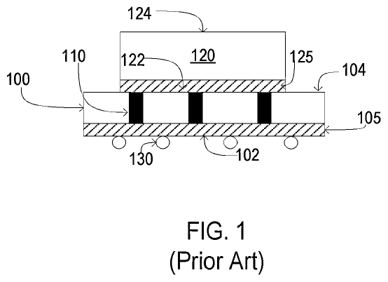

When stacking dies to form a 3DIC, a front side of the second die is coupled to a back side of the first die. As used herein the “front side” of a die is a side of the die including metallization layers of the die, with the “back side” of the die opposite to the front side. Hence, the back side of a conventional die does not include metallization layers. FIG. 1 shows a cross-section of a conventional semiconductor assembly including a first die 100 and a second die 120. The first die 100 has a front side 102 and a back side 104. The front side 102 of the first die 100 includes one or more metallization layers 105 of the first die 100. The metallization layers 105 form connections between devices comprising the first die 100. The metallization layers 105 are also referred to as “back end of line” (BEOL) layers. BEOL refers to a portion of semiconductor fabrication in which individual devices (e.g., transistors, capacitors, resistors, etc.) get interconnected with wiring on a wafer, referred to as a metallization layer. Hence, the metallization layer 105 of FIG. 1 is a layer that is formed in a manufacturing process for the first die 100 after layers where devices comprising the first die 100 are formed.

As shown in FIG. 1, the first die 100 includes through-silicon vias 110 coupled to one or more of the metallization layers 105. The through-silicon vias 110 include conductive material, so they are electrically coupled to the one or more metallization layers 105. The through-silicon vias 110 travel from the one or more metallization layers 105 to the back side 104 of the first die 100. A conductive portion of each of one or more of the through-silicon vias 110 is exposed at the back side 104 of the first die.

The second die 120 in FIG. 1 also has a front side 122 and a back side 124. The front side 122 of the second die 120 includes one or more metallization layers 125 of the second die 120. The metallization layers 125 of the second die 120 form connections between devices included in the second die 120, and are BEOL layers, as further described above, in various implementations. The front side 122 of the second die 120 is bonded to the back side 104 of the first die 100 in the semiconductor assembly of FIG. 1. The exposed conductive portions of the one or more through-silicon vias 110 on the back side 104 of the first die 100 are coupled to one or more of the metallization layers 125 of the second die 120. Coupling the through silicon vias 110 to the metallization layers 105 of the first die 100 and to the metallization layers 125 of the second die 120 provides interconnections between the first die 100 and the second die 120 for exchanging signals. Additionally, one or more solder bumps 130 are coupled to a metallization layer 105 of the first die 100, with the solder bumps 130 connecting the semiconductor assembly to a substrate or to another device. Other types of connectors are used to couple the semiconductor assembly to other devices in some implementations.

As shown in FIG. 1, the through-silicon vias 110 of the first die 100 form connections between the first die 100 and the second die 120. Hence, the number of through-silicon vias 110 in the first die 100 limits a number of interconnections between the first die 100 and the second die 120. While increasing a number of through-silicon vias 110 in the first die 100 increases a number of interconnections between the first die 100 and the second die 120, differences between thermal expansion of conductive material in a through-silicon via 110 and surrounding material increases thermally induced stress on the first die 100 as the number of through-silicon vias 110 increases. Introducing a “keep-out-zone” around a through-silicon via that specifies an area around the through-silicon via 110 where no circuit is implemented may reduce effects of thermal stress, but including keep-out-zones reduces an area of the first die 100 where circuits are implemented. Hence, using through-silicon vias 110 for coupling dies to each other places a limit on a density of interconnections between dies.

To provide a higher density of interconnections between dies that are stacked on one another, a front side of a first die is bonded to a front side of a second die according to implementations of the present disclosure. The front side of the first die includes front side metallization layers of the first die, while the front side of the second die includes front side metallization layers of the first die. Bonding a front side metallization layer of the first die to a front side metallization layer of the second die creates a density of interconnections between the first die and the second die that is controlled or limited only by the bond between the front side metallization layers of the different dies. Hence, bonding the front side metallization layer of the first die to the front side metallization layer of the second die enables a higher number of interconnections between the first die and the second die than would be formed from through-silicon vias in the first die. As numbers of devices included in dies increase over time, bonding the front side metallization layer of a die to a front side metallization layer of another die allows for the number of interconnections between the dies to more easily scale as numbers of devices included in dies increases.

To enable increased density of interconnections between a first die and a second die, the present specification sets forth various implementations of a semiconductor assembly that includes a first die having a front side metallization layer. The semiconductor assembly further includes a second die having a front side metallization layer bonded to the front side metallization layer of the first die. In some implementations, the semiconductor assembly further includes a set of through-silicon vias coupled to the front side metallization layer of the first die. The semiconductor assembly further includes a back side metallization layer with one or more of the through-silicon vias coupled to the back side metallization layer. In some implementations, one or more solder bumps are coupled to the back side metallization layer of the first die. The front side metallization layer of the first die is bonded to the front side metallization layer of the second die using a hybrid bond in some implementations. A pitch of interconnections between the front side metallization layer of the first die and the front side metallization layer of the second die is different than a pitch of the through-silicon vias in various implementations. In some implementations, a thickness of the first die is greater than a thickness of the second die.

In some implementations, the semiconductor assembly further includes an interconnect die having a metallization layer coupled to a portion of the front side metallization layer of the first die. The metallization layer of the interconnect die is coupled to a third die that is co-planar with the first die in various implementations. In some implementations, the metallization layer of the interconnect die is bonded to a front size metallization layer of the third die.

In some implementations, a portion of the front side metallization layer of the second die is bonded to the front side metallization layer of the first die and another portion of the front side metallization layer of the second die is bonded to a front side metallization layer of a third die that is co-planar with the first die. In various implementations, the second die is on top of the first die.

The present specification also sets forth various implementations of a method of manufacturing a semiconductor assembly that includes forming a set of through-silicon vias in a first die, each through-silicon via coupled to a front side metallization layer of the first die. The method also includes bonding a front side metallization layer of a second die to the front side metallization layer of the first die. In some implementations, bonding the front side metallization layer of the second die to the front side metallization layer of the first die includes removing a portion of a back side of the first die to reveal conductive portions of one or more through-silicon vias of the set and bonding the front side metallization layer of the second die to the front side metallization layer of the first die after revealing the conductive portions of the one or more through-silicon vias of the set.

In some implementations, the method further forms a back side metallization layer in the first die, with each of the set of through-silicon vias coupled to the back side metallization layer. In some implementations, forming the back side metallization layer includes removing a portion of a back side of the first die to reveal conductive portions of one or more of the through-silicon vias and forming the back side metallization layer after revealing the conductive portions of the one or more through-silicon vias, the back side metallization layer coupled to the conductive portions of the one or more through-silicon vias of the set.

In some implementations, a first carrier wafer is coupled to a back side of the first die. The back side metallization layer is formed in the first die further by removing the first carrier wafer from the back side of the first die, removing a portion of the back side of the first die to reveal conductive portions of one or more through-silicon vias of the set, and forming the back side metallization layer after revealing the conductive portions of the one or more through-silicon vias in some implementations. In some implementations, a second carrier wafer is coupled to a back side of the second die before removing the first carrier wafer from the back side of the first die.

In some implementations, a first carrier wafer is coupled to a front side of the first die. The front side metallization layer of the second die is bonded to the front side metallization layer of the first die further by removing a portion of a back side of the first die to reveal conductive portions of the one or more through-silicon vias of the set, repositioning the first carrier wafer from the front side of the first die to the back side of the first die, and bonding the front side metallization layer of the second die to the front side metallization layer of the first die after repositioning the first carrier wafer in some implementations. In some implementations repositioning the first carrier wafer from the front side of the first die to the back side of the first die include: applying a gap fill material surrounding the first die and repositioning the first carrier wafer from the front side of the first die to the back side of the first die after applying the gap fill material.

The following disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows include implementations in which the first and second features are formed in direct contact, and also include implementations in which additional features formed between the first and second features, such that the first and second features are in direct contact. Further, spatially relative terms, such as “beneath,” “below,” “lower,” “above,” “upper,” “back,” “front,” “top,” “bottom,” and the like, are used herein for ease of description to describe one element or feature's relationship to another element(s) or feature(s) as illustrated in the figures. Similarly, terms such as “front surface” and “back side” or “top surface” and “back side” are used herein to more easily identify various components, and identify that those components are, for example, on opposing sides of another component. The spatially relative terms are intended to encompass different orientations of the device in use or operation in addition to the orientation depicted in the figures.

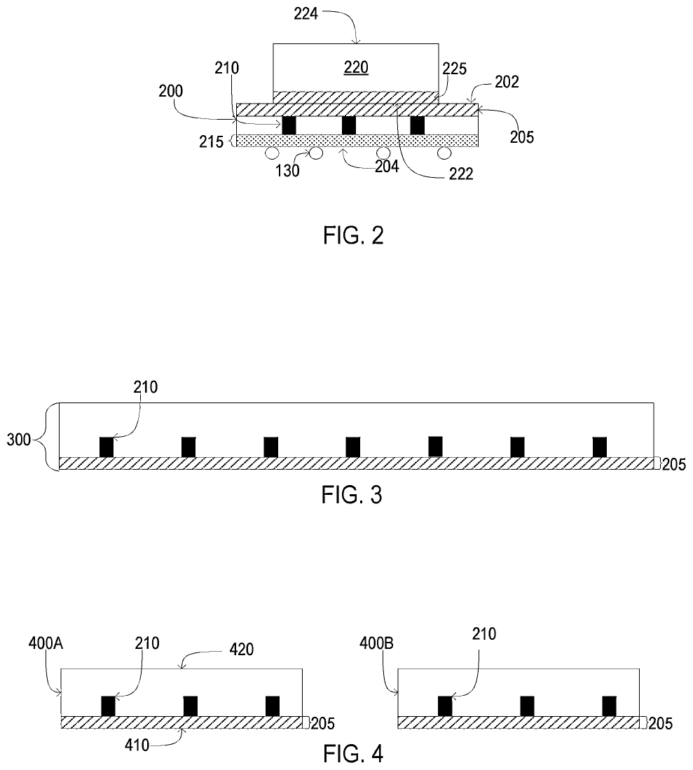

FIG. 2 is a cross-section of a semiconductor assembly where a metallization layer of a first die 200 is bonded to a metallization layer of a second die 220. The first die 200 has a front side 202 and a back side 204. The front side 202 of the first die 200 includes one or more front side metallization layers 205. The front side metallization layers 205 form connections between devices comprising the first die 200. The metallization layers 205 are also referred to as BEOL. Hence, a front side metallization layer 205 is formed in a manufacturing process for the first die 200 after layers where devices comprising the first die 200 are formed. The back side 204 of the first die 200 is opposite to the front side 202 of the first die 200.

The first die 200 includes through-silicon vias 210 coupled to one or more of the front side metallization layers 205. The through-silicon vias 210 include conductive material, so they are electrically coupled to one or more of the front side metallization layers 205. The through-silicon vias 210 each have an end coupled to a front side metallization layer 205 in various implementations. An opposite end of a through-silicon via 210 is coupled to a back side metallization layer 215 of the first die 200. Hence, the through-silicon vias 210 traverse a width of the first die 200 to conductively couple a front side metallization layer 205 to a back side metallization layer 215. In some implementations, the one or more back side metallization layers 215 include layers of metallization and interlevel dielectric material, as well as conductive structures such as vias, traces, and pads. Hence, the one or more back side metallization layers 215 are one or more redistribution layers for a first die 200.

A front side metallization layer 225 of a second die 220 is bonded to a front side metallization layer 205 of the first die 200, as shown in FIG. 2. In various implementations, a hybrid bond is used to bond the front side metallization layer 205 of the first die 200 to the front side metallization layer 225 of the second die 200. As used herein, a hybrid bond refers to a permanent bond that combines a dielectric bond with embedded metal to form interconnections between the first die 200 and the second die 220. Using hybrid bonding directly bonds dielectric and interconnect features between the front side metallization layer 205 of the first die 220 and the front side metallization layer 225 of the second die 220. Hence, hybrid bonding directly couples conductive material from a front side metallization layer 205 of the first die 200 to conductive material from the front side metallization layer 225 of the second die 220, allowing a greater density of interconnections between the first die 200 and the second die 220. Referring to FIG. 1, in conventional configurations where the back side 104 of a first die 100 is bonded to a front side 122 of a second die 120, a density of interconnections between the first die 100 and the second die 120 is limited by a density of through-silicon vias 110 formed in the first die 100. In contrast, bonding the front side metallization layer 205 of the first die 200 to the front side metallization layer 225 of the second die 220, as shown in FIG. 2, has a density of interconnections between the first die 200 and the second die 220 based on a density of interconnections through the hybrid bond between the dies, enabling an increased density of interconnections between the first die 200 and the second die 220.

The one or more front side metallization layers 225 of the second die 220 are included in a front side 222 of the second die 220. The second die 220 also has a back side 224 that is opposite to the front side 222 of the second die 200. In the example shown by FIG. 2, the back side 224 of the second die 220 does not include one or more metallization layers; however, in other implementations, the back side of the second die 220 also includes one or more metallization layers.

As the through-silicon vias 210 of the first die 200 couple a front side metallization layer 205 of the first die 200 to a back side metallization layer 215 of the first die 200, the through-silicon vias 210 allow the front side metallization layer 225 of the second die 200 to be conductively coupled to the back side metallization layer 215 of the first die 200. An interconnection between the front side metallization layer 225 of the second die 220 and the front side metallization layer 205 of the first die 200 allows the front side metallization layer 225 of the second die 220 to leverage connective connections from the front side metallization layer 205 of the first die 200 formed by the through-silicon vias 210 to transmit and to receive signals from the front side metallization layer 225 of the second die 200.

In the semiconductor assembly shown by FIG. 2, one or more solder bumps 130 are coupled to a back side metallization layer 215 of the first die 200. The solder bumps 130 connect the semiconductor assembly to a substrate or to another device. Other types of connectors are used to couple the semiconductor assembly to other devices in some implementations. A solder bump 130, a front side metallization layer 205 of the first die 200, the a through silicon via 210, the back side metallization layer 215 of the first die 200, and the front side metallization layer 225 of the second die 220 form a conductive connection between the second die 200 and one or more components external to the semiconductor assembly in various implementations.

FIGS. 3-12 show steps in an example manufacturing process for a semiconductor assembly with a second die bonded to a first die. Beginning with FIG. 3, multiple dies are formed on a wafer 300. The wafer 300 includes one or more front side metallization layers 205, with each die on the wafer 300 including the one or more front side metallization layers 205. In some examples, the front side metallization layers 205 include layers of metallization and interlevel dielectric material, as well as conductive structures such as vias, traces, and pads. A front side metallization layer 205 forms connections between the circuit components composed in a die substrate to implement the functional circuit blocks of the die. For example, the one or more front side metallization layers 205 implement a die-level redistribution layer structure created during the die fabrication process, such as a BEOL structure.

Additionally, each die included in the wafer 300 includes a set of through-silicon vias 210. Each through-silicon via 210 is coupled to a front side metallization layer 205 of a die. For example, each through-silicon via 210 has a first end that is coupled to a front side metallization layer 205. A through-silicon via 210 passes through the wafer for a length and has a second end that is opposite to the end coupled to the front side metallization layer 205. In various implementations, a through-silicon via 210 is etched into the wafer 300 through lithography, such as through photolithography. After etching the through-silicon via 210, an insulating layer is applied to the wafer 300 and through-silicon via to electrically isolate a subsequently applied conductive material from the wafer 300. In various implementations, the insulating layer is silicon dioxide, while silicon nitride or alumina are applied as the insulating layer in other implementations. The insulating layer is deposited using different methods in different implementations. A barrier layer is applied to the insulating layer, with the barrier layer preventing diffusion or electromigration of the subsequently applied conductive material during subsequent operation. In various implementations, the barrier material is tantalum nitride, although platinum or other materials are used as the barrier material in other implementations. The barrier material is applied through physical vapor deposition, atomic layer deposition, or through other methods in various implementations.

A seed layer of the conductive material is applied to the barrier material. In some implementations, the seed layer is applied through physical vapor deposition, with other methods used to apply the conductive material in other implementations. The conductive material is applied to the seed layer to form a through-silicon via 210. In various implementations, the conductive material is applied to the seed layer through electrochemical deposition, while other methods are used to apply the conductive material in other implementations. Further, in some implementations, the seed layer comprises a different conductive material than the conductive material applied to the seed layer, while in other implementations, a common conductive material comprises the seed layer and is applied to the seed layer. However, in other implementations, the through-silicon vias 210 are formed using any suitable method or combination of methods.

In various implementations, the dies included on the wafer 300 are tested for reliability against one or more metrics. For example, a probe is coupled to a pad of at least one die included in the wafer and applies one or more signals to dies in the wafer 300 to test the dies. For example, the probe applies one or more logic patterns to dies in the wafer to apply thermal stress or voltage stress to dies in the wafer to identify temperature-related defects in dies or other failure mechanisms for dies in the wafer. Dies that do not pass one or more of the tests are identified and are subsequently discarded. Hence, testing the dies on the wafer allow identification of dies that are likely to fail, allowing the identified dies to be excluded from inclusion in semiconductor assemblies.

After testing the dies included in the wafer 300, the wafer 300 is diced as shown in FIG. 4. Dicing the wafer 300 divides the wafer 300 into discrete dies 400A and 400B. As shown in FIG. 4, each die 400A and 400B has a front side 410 and a back side 420. As further described above in conjunction with FIG. 1, the front side 410 of die 400A, 400B includes the one or more front side metallization layers 205, and the back side 420 of die 400A, 400B is opposite to the front side 410. Each die 400A, 400B includes a set of through-silicon vias 210. Each through silicon via 210 in the die 400A, 400B is coupled to the front side metallization layer 205 of the die 400A, 400B.

While FIG. 4 shows the wafer 300 diced into two dies 400A, 400B, the wafer 300 can be diced into any number of dies in other implementations. In some implementations, the wafer 300 is scribed into different dies by being partially cut by a cutting tool then broken along the scribe lines to form the different dies. In other implementations, the wafer 300 is sawed using a cutting blade that cuts through the wafer 300 to form different dies. As another example, a laser is used to cut the wafer 300 into different dies, while in other implementations, plasma dicing us used to etch trenches into a wafer using a plasma gas to divide the wafer 300 into different dies. In various implementations, the dies 400A, 400B are dies that passed the one or more tests described above, resulting in the dies 400A, 400B having at least a threshold reliability based on the testing.

In addition to being diced into individual dies 400A, 400B, the wafer 300 is thinned, reducing a thickness of the wafer 300 by removing material from the back side 420 of the dies 400A, 400B. In some implementations, the wafer 300 is thinned before being diced. However, in other implementations, different dies 400A, 400B are thinned after being cut from the wafer 300. Thinning removes an amount of the wafer 300 between a second end of the through-silicon vias 210 that is not coupled to the front side metallization layer 205 and the back side 420 of a die 400A, 400B. In various implementations, a die 400A, 400B or the wafer 300 is thinned using a mechanical grinding process, while in other implementations, a die 400A, 400B or the wafer 300 is thinned using a chemical mechanical polishing process. However, different grinding or polishing processes are used in different implementations.

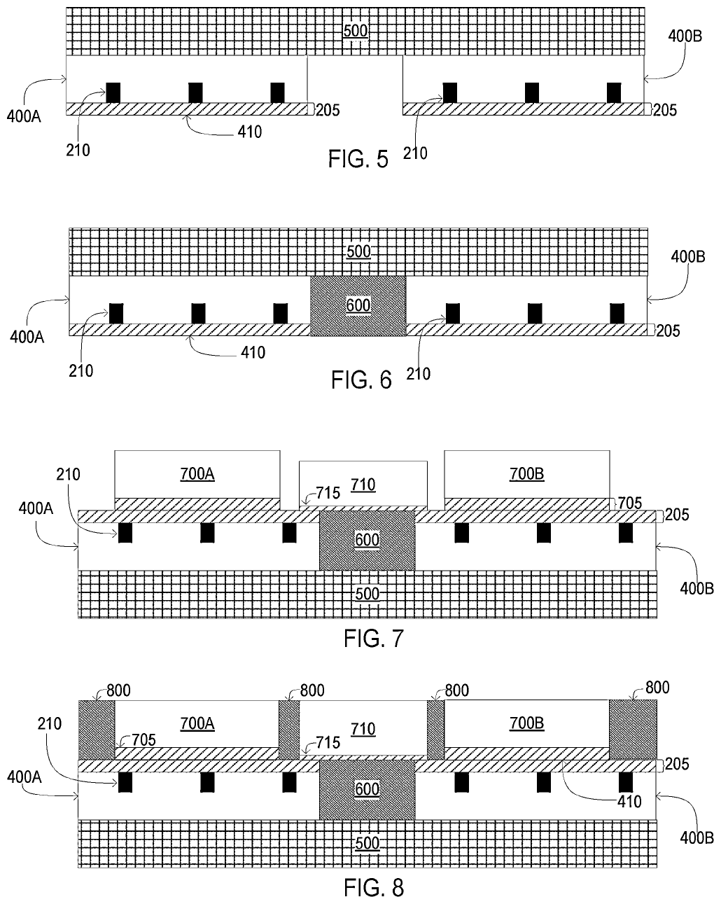

With the thickness of the dies 400A, 400B reduced through thinning, FIG. 5 shows application of a carrier wafer 500 to the back side 420 of the dies 400A, 400B. The carrier wafer 500 is bonded to the back side 420 of the dies 400A, 400B using an adhesive, such as a polymer-based adhesive, in various implementations. The carrier wafer 500 is mechanically robust and has high resistance to chemicals and to temperature, simplifying handling and processing of the dies 400A, 400B during fabrication. Examples of the carrier wafer 500 include a quartz wafer, a glass wafer, a silicon wafer, a gallium arsenide wafer, an indium phosphide wafer, or a silicon carbide wafer.

FIG. 6 shows application of a gap fill material between the dies 400A, 400B while the dies 400A, 400B are bonded to the carrier wafer 500. The gap fill material 600 surrounds the dies 400A, 400B and fills openings between adjacent dies. The gap fill material 600 is an inorganic dielectric in some implementations. Example inorganic dielectric materials include silicon oxide or other oxide-based dielectrics. Other materials are used for the gap fill material 600 in other implementations.

For further explanation, FIG. 7 shows bonding a front side metallization layer 705 of a die 700A, 700B to a front side metallization layer 205 of die 400A, 400B respectively. FIG. 7 shows bonding of a front side metallization layer 705 of die 700A to a front side metallization layer 205 of die 400A, and bonding of a front side metallization layer 705 of die 700B to a front side metallization layer 205 of die 400B. While FIG. 7 shows two combinations of a die coupled, face-to-face, to another die, readers will appreciate any number of combinations of are possible. In various implementations, a hybrid bond is used to bond the front side metallization layer 705 of the die 700A, 700B to the front side metallization layer 205 of the die 400A, 400B. A hybrid bond, as the term is used here, refers to a permanent bond that combines a dielectric bond with embedded metal to form interconnections between dies. Using hybrid bonding directly bonds dielectric and interconnect features between the front side metallization layer 205 of the die 400A, 400B and the front side metallization layer 705 of die 700A, 700B. Hence, hybrid bonding directly couples conductive material from a front side metallization layer 205 of die 400A, 400B to conductive material from the front side metallization layer of die 700A, 700B. Bonding the front side metallization layer 705 of the die 700A, 700B to the front side metallization layer 205 of the die 400A, 400B allows for a greater density of interconnections between the dies. Said another way, a pitch of interconnections between the front side metallization layer of die 400A, 400B and the front side metallization layer of the die 700A, 700B is different than a pitch of the through-silicon vias 110. Referring to FIG. 1, in conventional configurations where the back side 104 of a first die 100 is bonded to a front side 122 of a second die 120, a density of interconnections between the first die 100 and the second die 120 is limited by a density of through-silicon vias 110 formed in the first die 100. In contrast, bonding the front side metallization layer 205 of die 400A, 400B to the front side metallization layer 705 of the second die 700A, 700B, as shown in FIG. 7, has a density of interconnections between the dies based on a density of interconnections through the hybrid bond, which allows for a greater density of interconnections.

Each die 700A,700B includes one or more front side metallization layers 705. In some examples, the front side metallization layers 705 include layers of metallization and interlevel dielectric material, as well as conductive structures such as vias, traces, and pads. A front side metallization layer 705 forms connections between the circuit components composed in a die substrate of die 700A, 700B to implement the functional circuit blocks of the die 700A, 700B. For example, the front side metallization layers 205 implement a die-level redistribution layer structure created during the die fabrication process, such as a BEOL structures. In various implementations, die 400A, 400B has a different thickness than die 700A, 700B. For example, die 400A has a thickness that is greater than a thickness of die 700A.

For purposes of illustration, FIG. 7 shows an optional interconnect die 710 coupled to die 400A and to die 400B. In other implementations, the interconnect die 710 is not coupled to the die 400A and die 400B. The interconnect die 710 in the example of FIG. 8 includes, in a front side, one or more metallization layers 715. The one or more metallization layers 715 comprise layers of metallization and interlevel dielectric material, as well as conductive structures such as vias, traces, and pads. The front side of the interconnect die 710 is coupled to a portion of front side 410 of die 400A and of die 400B. A metallization layer 205 in the front side 410 of die 400A, 400B is coupled to a portion of a metallization layer 715 of the interconnect die 710. The interconnect die 710 allows signals to be routed from the die 400A to die 400B, and vice versa, through the one or more metallization layers 715 of the interconnect die 710. Coupling the front side metallization layer 205 of die 400A, 400B to the metallization layer 715 of the interconnect die 710 increases a number of interconnections between the die 400A, 400B and the interconnect die 710, as described above. In some implementations, the interconnect die 710 is a passive die including the one or more metallization layers 715, without active components. In other implementations, the interconnect die 710 is an active die that includes one or more active components for routing signals between the die 400A and die 400B.

As shown in FIG. 7, die 400A is co-planar to die 400B, with a surface of die 400A and a surface of die 400B coupled to the front side of the interconnect die 710 in a common plane. In the example of FIG. 7, the interconnect die 710 is coupled to front side of die 400A and the front side of die 400B. In other examples, the interconnect die 710 is coupled to a back side of the die 400B and the front side of die 400A. In such an implementation, the interconnect die 710 includes a metallization layer 715 that is coupled to a conductive portion of a through-silicon via 210 of the die 400B, with the through-silicon via 210 of the die 400B coupling the metallization layer 715 of the interconnect die 710 to the front side metallization layer 205 of the die 400B.

While FIG. 7 shows an implementation where a die 700A, 700B is positioned on top of a die 400A, 400B, allowing vertical stacking, in other implementations, the semiconductor assembly includes a die 400A, 400B in a common plane without a die 700A, 700B. In such an implementation, an interconnect die 710 couples the die 400A to the die 400B, as further described above. The metallization layer 715 of the interconnect die 710 is bonded to the front side metallization layer 205 of die 400A and the front side metallization layer 205 of die 400B that is co-planar with the die 400A. Such a configuration allows dies that are laterally adjacent to each other to leverage the increased number of interconnections from bonding metallization layers in different dies to each other to improve communication of signals, power, and ground between dies.

FIG. 8 shows application of additional gap fill material 800 between the dies 700A, 700B. The additional gap fill material 800 surrounds the dies 700A, 700B and fills spaces between the dies 700A, 700B. Further, the additional gap fill material 800 fills openings between the dies 700A, 700B and the interconnect die 710 in implementations that include an interconnect die 710. In various implementations, the additional gap fill material 800 has a height that equals a distance between the front side 410 of die 400A, 400B and a back side of die 700A, 700B. The additional gap fill material 800 is an inorganic dielectric material in some implementations. Example inorganic dielectric materials include silicon oxide or other oxide-based dielectrics. Other materials are used for the additional gap fill material 800 in other implementations. The gap fill material 600 and the additional gap fill material 800 are a common material in some implementations, while in other implementations the gap fill material 600 and the additional gap fill material 800 are different materials.

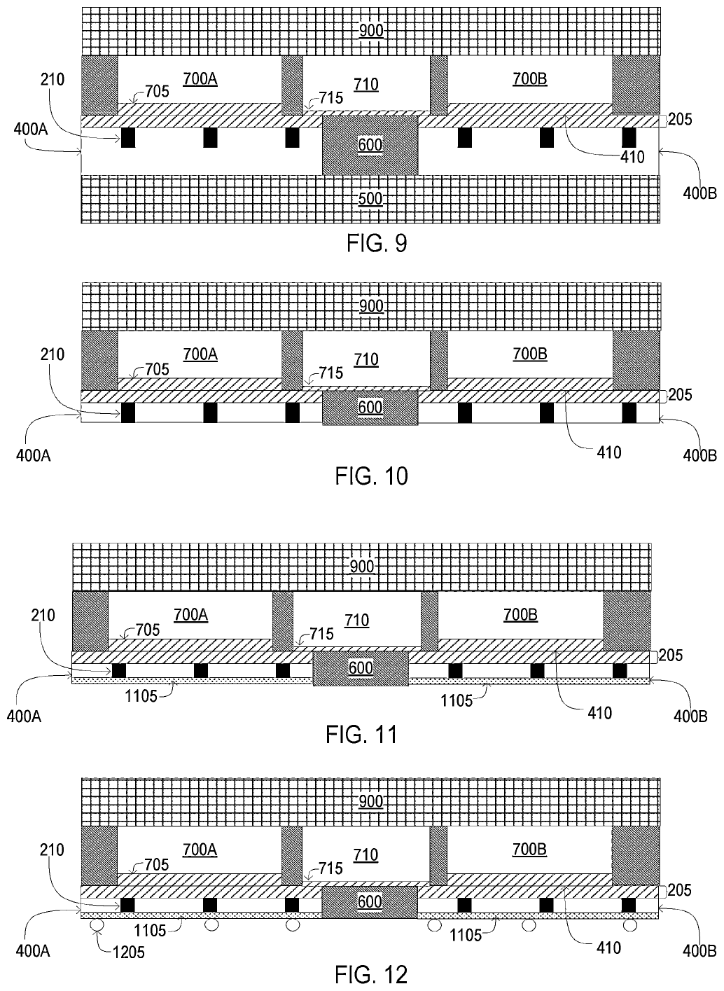

In FIG. 9, a second carrier wafer 900 is applied to the back sides of the dies 700A, 700B. In implementations including an interconnect die 710, the second carrier wafer 900 is bonded to a back side of the interconnect die 710. The second carrier wafer 900 is bonded to the back sides of the dies 700A, 700B using an adhesive, such as a polymer-based adhesive, in various implementations. The second carrier wafer 900 is mechanically robust and has high resistance to chemicals and to temperature, simplifying handling and processing of dies 400A, 400B and dies 700A, 700B during fabrication. Examples of the second carrier wafer 900 include a quartz wafer, a glass wafer, a silicon wafer, a gallium arsenide wafer, an indium phosphide wafer, or a silicon carbide wafer. In various implementations, the second carrier wafer 900 and the carrier wafer 500 are a common material, while in other implementations the second carrier wafer 900 and the first carrier wafer 500 are different materials. Hence, FIG. 9 shows the first carrier wafer 500 bonded to the back side 420 of the dies 400A, 400B, and the second carrier wafer 900 bonded to back sides of the dies 700A, 700B.

With the second carrier wafer 900 bonded to the back side of the dies 700A, 700B, the first carrier wafer 500 is removed from the back side 420 of dies 400A, 400B, as shown in FIG. 10. In various implementations, the carrier wafer 500 is removed from dies 400A, 400B by weakening or by removing an adhesive bonding the carrier wafer 500 to the back sides 420 of dies 400A, 400B. For example, the adhesive is exposed to light from a laser or other source to weaken its adhesive strength. In another example, the adhesive bonding the carrier wafer 500 to the back side 420 of dies 400A, 400B is chemically removed.

As shown in FIG. 10, the back side 420 of dies 400A, 400B are thinned after the carrier wafer 500 is removed. Thinning the dies 400A, 400B reduces a thickness of the dies 400A, 400B by removing material from the back side 420 of the dies 400A, 400B. Thinning the dies 400A, 400B includes removes an amount of a die 400A, 400B so a conductive portion of a second end of the through-silicon vias 210 that is not coupled to the front side metallization layer 205 is exposed on the back side 420 of each of the dies 400A, 400B. As further described below, exposing the conductive portion of the second end of a through-silicon via 210 allows for connections to be formed to one or more of the front side metallization layers 205 using the through-silicon vias 210. In various implementations, die 400A, 400B is thinned using a mechanical grinding process, a chemical mechanical polishing process, or another process as will occur to those of skill in the art.

To connect components or devices to one or more front side metallization layers 205 of a die 400A, 400B, one or more back side metallization layers 1105 are formed on the back side 420 of the die 400A, 400B, as shown in FIG. 11. A back side metallization layer 1105 is coupled to one or more through-silicon vias 210 included in die 400A, 400B. In various implementations, a back side metallization layer 1105 is coupled to the conductive portion of the second end of a through-silicon via 210 exposed when the back side 420 of die 400A, 400B is thinned, as further described above in conjunction with FIG. 10. Hence, a through-silicon via 210 in die 400A, 400B couples a front side metallization layer 205 to a back side metallization layer 1105. In some examples, the one or more backside metallization layers 1105 include layers of metallization and interlevel dielectric material, as well as conductive structures such as vias, traces, and pads. Hence, the one or more back side metallization layers 1105 are one or more redistribution layers for die 400A, 400B.

For further illustration, FIG. 12 shows solder bumps 1205 coupled to a back side metallization layer 1105. The solder bumps 1205 allow coupling of die 400A, 400B to a package substrate and allow coupling of one or more other components to die 400A, 400B. As a solder bump 1205 is coupled to a back side metallization layer 1105 signals are directed between the solder bump 1205 and a front side metallization layer 205 of die 400A, 400B using the through-silicon vias 210 of die 400A, 400B. As the front side metallization layer 205 of die 400A, 400B is bonded to the front side metallization layer 705 of die 700A, 700B, conductive connections from the bonding allows signals to be directed from a solder bump 1205 to die 700A, 700B and vice versa. While FIG. 12 shows coupling of solder bumps 1205 to the back side metallization layer 1105 of die 400A, 400B, in other implementations, different types of conductive connectors are coupled to the back side metallization layer 1105 for coupling die 400A, 400B to a package substrate or to another device or component.

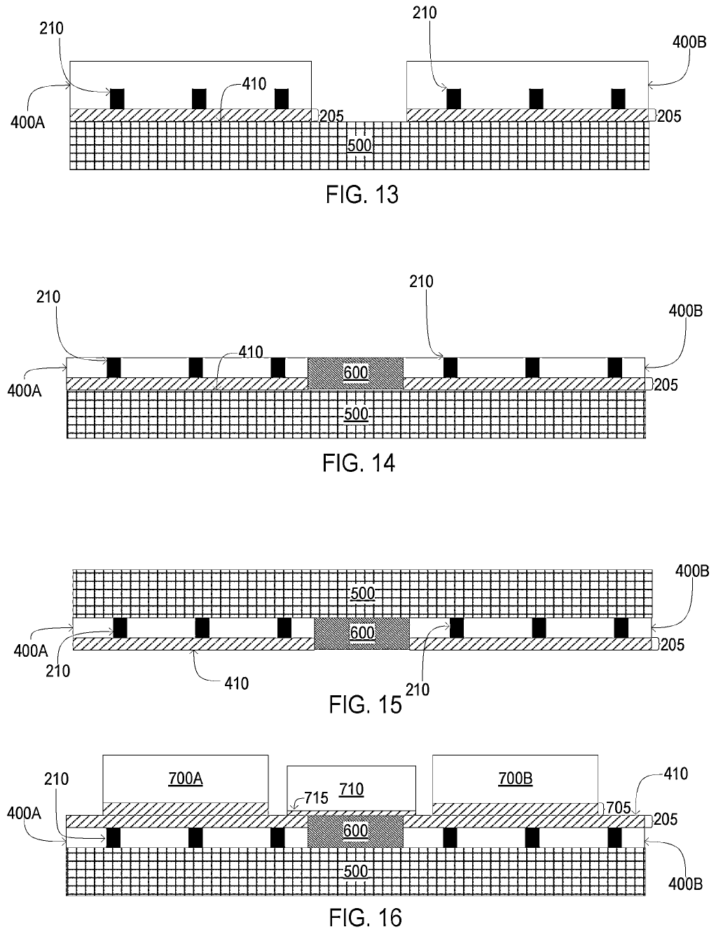

FIGS. 3-12 depict steps in a fabrication process where a carrier wafer 500 is initially bonded to a back side 420 of dies 400A, 400B. FIGS. 13-16 depict steps in another fabrication process in which the carrier wafer 500 is bonded to the front side 410 of die 400A, 400B. In FIG. 13, a wafer 300 has been diced into dies 400A, 400B and thinned, as further described above in conjunction with FIGS. 3 and 4. The carrier wafer 500 is bonded to the front side 410 of the first dies 400A, 400B using an adhesive, such as a polymer-based adhesive, in various implementations. The carrier wafer 500 is mechanically robust and has high resistance to chemicals and to temperature, simplifying handling and processing of the first dies 400A, 400B during fabrication. Examples of the carrier wafer 500 include a quartz wafer, a glass wafer, a silicon wafer, a gallium arsenide wafer, an indium phosphide wafer, or a silicon carbide wafer. As further described above in conjunction with FIG. 3, the front side 410 of die 400A, 400B includes a front side metallization layer 205, so bonding the carrier wafer 500 to the front side 410 of die 400A, 400B bonds the carrier wafer 500 to the front side metallization layer 205.

With the carrier wafer 500 bonded to the front side 410 of die 400A, 400B, FIG. 14 shows application of a gap fill material 600 between die 400A, 400B, as further described above in conjunction with FIG. 6. Additionally, the back sides 420 of die 400A, 400B are thinned, as shown in FIG. 14. The gap fill material 600 is also thinned, so the gap fill material 600 and dies 400A, 400B have substantially equal heights. Thinning die 400A, 400B reduces a thickness of die 400A, 400B by removing material from the back side 420. Thinning die 400A, 400B includes removing an amount of die 400A, 400B so a conductive portion of a second end of the through-silicon vias 210 that is not coupled to the front side metallization layer 205 is exposed on the back side 420. As further described above, exposing the conductive portion of the second end of a through-silicon via 210 allows for connections to be formed to one or more of the front side metallization layers 205 using the through-silicon vias 210. In various implementations, die 400A, 400B is thinned using a mechanical grinding process, a chemical mechanical polishing process, or another process as will occur those of skill in the art.

After exposing the conductive portions of the through-silicon vias 210 by thinning die 400A, 400B, the carrier wafer 500 is repositioned from the front side 410 of dies 400A, 400B to the back side 420 of dies 400A, 400B, as shown in FIG. 15. Such repositioning exposes the one or more front side metallization layers 205 of dies 400A, 400B. As further described above, the carrier wafer 500 is removed from die 400A, 400B by weakening or by removing an adhesive bonding the carrier wafer 500 to the front side 410 of die 400A, 400B. For example, the adhesive is exposed to light from a laser or other source to weaken its adhesive strength. In another example, the adhesive bonding the carrier wafer 500 to the front side 410 of die 400A, 400B is chemically removed.

The carrier wafer 500 is removed from the front side 410 of die 400A, 400B, as further described above in conjunction with FIG. 10, and bonded to the back side 420 of die 400A, 400B using an adhesive, as further described above in conjunction with FIG. 5. FIG. 15 shows the carrier wafer 500 removed from the front side 410 of die 400A, 400B and bonded to the back side 420 of die 400A, 400B. In other implementations, the carrier wafer 500 is removed from the front side 410 of die 400A, 400B, as further described above in conjunction with FIG. 10, and a different carrier wafer is bonded to the back side 420 die 400A, 400B, as further described above in conjunction with FIG. 5. Repositioning the carrier wafer 500 from the front side 410 to the back side 420 die 400A, 400B exposes the front side metallization layers 205 of die 400A, 400B, while allowing the carrier wafer 500 to provide mechanical stability and resistance to chemicals and temperature for die 400A, 400B during fabrication. As shown in FIG. 14, the conductive portions of the through-silicon vias 210 of the die 400A, 400B are revealed and die 400A, 400B is thinned while the carrier wafer 500 is coupled to the front side 410 of die 400A, 400B, then the carrier wafer 500 is repositioned to the back side 420 of the die 400A, 400B after the conductive portions of the through-silicon vias 210 are revealed.

After repositioning the carrier wafer 500 to the back side 420 of die 400A, 400B, FIG. 16 shows bonding a front side metallization layer 705 of a die 700A, 700B to a front side metallization layer 205 of die 400A, 400B respectively. For purposes of illustration, FIG. 16 shows bonding of a front side metallization layer 705 of die 700A to a front side metallization layer 205 of die 400A and bonding of a front side metallization layer 705 of die 700B to a front side metallization layer 205 of die 400B. In various implementations, a hybrid bond is used to bond the front side metallization layer 705 of die 700A, 700B to the front side metallization layer 205 of die 400A, 400B.

FIG. 16 shows an example in which an interconnect die 710 is coupled die 400A, 400B, as further described above in conjunction with FIG. 7. However, in other implementations, the interconnect die 710 is not coupled to die 400A, 400B. Similarly, FIG. 16 shows an example depicting two dies 400A, 400B that are each coupled to a corresponding die 700A, 700B. However, in other implementations, different numbers of dies are coupled to corresponding dies in a face-to-face orientation.

After bonding a front side metallization layer 205 of die 400A, 400B to a front side metallization layer 705 of die 700A, 700B, additional gap fill material 800 is applied to fill spaces between die 700A, 700B, and interconnect die 710 (if included), as further described above in conjunction with FIG. 8. After applying the additional gap fill material 800, a second carrier wafer 900 is bonded to the back side of die 700A, 700B, as further described above in conjunction with FIG. 9. One or more back side metallization layers 1105 are formed in the back side of die 400A, 400B, as further described above in conjunction with FIG. 11. A back side metallization layer 1105 is coupled to one or more through-silicon vias 210 in die 400A, 400B, with the through silicon vias 210 also coupled to a front side metallization layer 205 of die 400A, 400B. One or more solder bumps 1205 are coupled to the back side metallization layer 1105 of die 400A, 400B, as further described above in conjunction with FIG. 12.

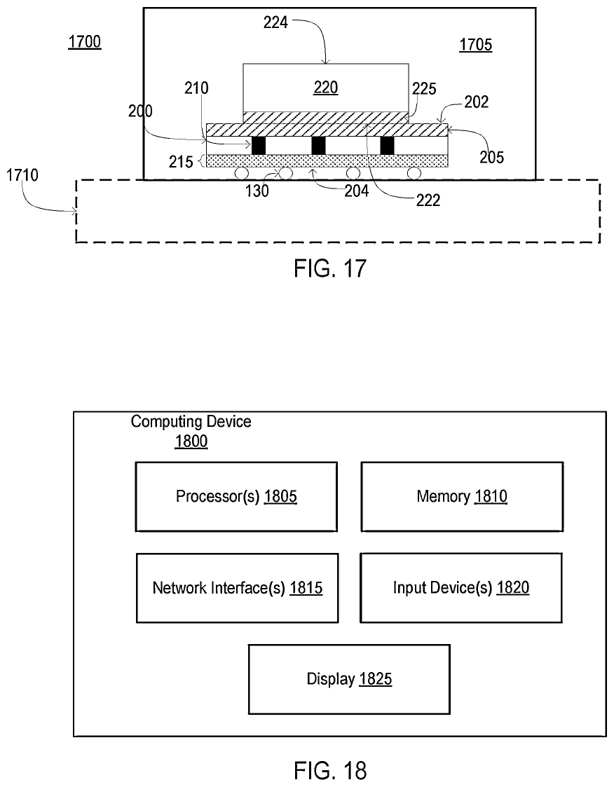

FIG. 17 is a cross-sectional diagram of an example integrated circuit device 1700 including a semiconductor assembly having a front side metallization layer of a first die bonded to a front side metallization layer of a second die. The example integrated circuit device 1700 can be implemented in a variety of computing devices, including mobile devices, personal computers, peripheral hardware components, gaming devices, set-top boxes, smart phones, and the like (as shown in FIG. 18). The example integrated circuit device 1700 of FIG. 17 includes a component 1705. The component 1705 includes a first die 200 coupled to a second die 220. Each die is a block of semiconducting material such as silicon onto which a functional integrated circuit is fabricated. As an example, the first die 200 or the second die 220 includes a processor such as a Central Processing Unit (CPU), a Graphics Processing Unit (GPU), or other processor as can be appreciated. As further described above in conjunction with FIGS. 2-16, a front side metallization layer 205 of the first die 200 is bonded to a front side metallization layer 225 of the second die 220 through a hybrid bond. Bonding the front side metallization layer 205 of the first die 200 to a front side metallization layer 225 of the second die 220 allows for a greater number of interconnections between the first die 200 and the second die 220 than other techniques for bonding the first die 200 to the second die 220. With the front side metallization layer 205 of the first die 200 bonded to the front side metallization layer 225 of the second die 220, the first die 200 includes a back side metallization layer 215 for coupling the first die 200 to a substrate 1710. The first die 200 includes a set of through-silicon vias 210 coupling a back side metallization layer 215 to the front side metallization layer 205 for exchanging signals between the front side metallization layer 205 and the back side metallization layer 215.

As an example, the first die 200 (or the second die 220) includes a processor 1805 of a computing device 1800 as shown in FIG. 18. The computing device 1800 is implemented, for example, as a desktop computer, a laptop computer, a server, a game console, a smart phone, a tablet, and the like. In addition to one or more processors 1805, the computing device 1800 includes memory 1810. The memory 1810 includes Random Access Memory (RAM) or other volatile memory. The memory 1810 also includes non-volatile memory such as disk storage, solid state storage, and the like.

In some implementations, the computing device 1800 also includes one or more network interfaces 1815. In some implementations, the network interfaces 1815 include a wired network interface 1815 such as Ethernet or another wired network connection as can be appreciated. In some implementations, the network interfaces 1815 include wireless network interfaces 1815 such as Wi-Fi, BLUETOOTH®, cellular, or other wireless network interfaces 1815 as can be appreciated. In some implementations, the computing device 1800 includes one or more input devices 1820 that accept user input. Example input devices 1820 include keyboards, touchpads, touch screen interfaces, and the like. One skilled in the art will appreciate that, in some implementations, the input devices 1820 include peripheral devices such as external keyboards, mice, and the like.

In some implementations, the computing device 1800 includes a display 1825. In some implementations, the display 1825 includes an external display connected via a video or display port. In some implementations, the display 1825 is housed within a housing of the computing device 1800. For example, the display 1825 includes a screen of a tablet, laptop, smartphone, or other mobile device. In implementations where the display 1825 includes a touch screen, the display 1825 also serves as an input device 1820.

The component 1705 is coupled to a substrate 1710. The substrate 1710 is a portion of material that mechanically supports the component 1705. In some implementations, the substrate 1710 also electrically couples various components mounted to the substrate 1710 via conductive traces, tracks, pads, and the like. For example, the substrate 1710 electrically couples the first die 200 to one or more other components via a solder bump 130 (or other connector). As the solder bump 130 is coupled to the back side metallization layer 215 of the first die 200, the through-silicon vias 210 of the first die 200 allow conductive connections between the one or more other components and the front side metallization layer 205 of the first die 200, as well as the front side metallization layer 225 of the second die 220. In some implementations, the substrate 1710 includes a printed circuit board (PCB), while in other implementations the substrate 1710 is another semiconductor device, like the first die 200 or the second die 220 (which may include active components therein). In some implementations, the component 1705 is coupled to the substrate 1710 via a socket (not shown), where the component 1705 is soldered to or otherwise mounted in the socket. In other implementations, as shown in FIG. 17, the component 1705 is directly coupled to the substrate 1710 via a direct solder connection or other connection as can be appreciated. In some implementations, the component 1705 is coupled to the substrate 1710 using a land grid array (LGA), pin grid array (PGA), or other packaging technology as can be appreciated.

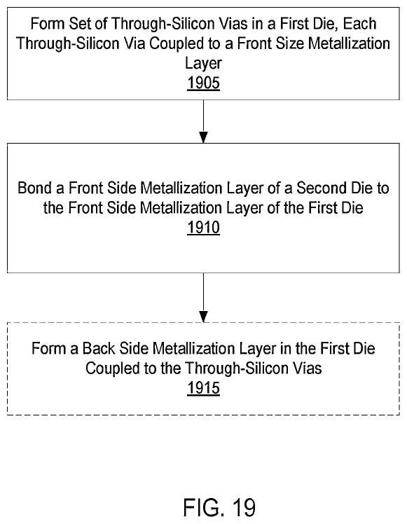

For further explanation, FIG. 19 sets forth a flow chart illustrating an example method for manufacturing a semiconductor assembly with a second die 220 bonded to a first die 200. The method shown in FIG. 19 includes forming 1905 a set of through-silicon vias 210 in the first die 200, as further described above in conjunction with FIG. 3. Each through-silicon via 210 of the first die 200 is coupled to a front side metallization layer 205 of the first die 200. A through-silicon via 210 includes conductive material, with an end of the through-silicon via 210 coupled to a front side metallization layer 205 of the first die 200. In various implementations, the front side metallization layer 205 of the first die 200 is included in a front side 204 of the first die 200.

The method further includes bonding 1910 a front side metallization layer 225 of a second die 220 to the front side metallization layer 205 of the first die 200. In various implementations, the front side metallization layer 225 of the second die 220 is bonded 1910 to the front side metallization layer 205 of the first die 200 using a hybrid bond. Bonding 1910 the front side metallization layer 225 of the second die 220 to the front side metallization layer 205 of the first die 200 increases a number of interconnects between the first die 200 and the second die 220 relative to conventional bonding methods where the front side metallization layer 225 of the second die 220 is bonded to a back side 204 of the first die 200 and the through-silicon vias 210 of the first die 200 form the interconnections between the first die 200 and the second die 220. Bonding 1910 the front side metallization layer 225 of the second die 220 to the front side metallization layer 205 of the first die 200 allows the density of interconnects between the first die 200 and the second die 220 to differ from a density of the through-silicon vias 210 in the first die 200. In some implementations, a portion of a back side 204 of the first die 200 is removed to reveal conductive portions of one or more through-silicon vias 210 of the set, and the front side metallization layer 225 of the second die 220 is bonded 1910 to the front side metallization layer 205 of the first die 200 after revealing the conductive portions of the one or more through-silicon vias 210 of the set, as further described above in conjunction with FIGS. 14-16. Bonding the front side metallization layer 205 of the first die 200 to the front side metallization layer 225 of the second die 220 allows the number of interconnects between the first die 200 and the second die 220 to be greater than a number of through-silicon vias 210 in the first die 200.

In some implementations, a first carrier wafer 500 is coupled to a front side 202 of the first die 200, with the first carrier wafer 500 repositioned from the front side 202 of the first die 200 to the back side 204 of the first die 200. A portion of a back side 204 of the first die 200 is removed to reveal conductive portions of one or more through-silicon vias 210 of the set, as further described above in conjunction with FIGS. 13 and 14. After revealing the conductive portions of the one or more through-silicon vias 210, the first carrier wafer 500 is repositioned from the front side 202 of the first die 200 to the back side 204 of the first die 200. In various implementations, a gap fill material is applied to surround the first die 200, and the first carrier wafer 500 is repositioned to the back side 204 of the first die 200 after the gap fill material is applied, as further described above in conjunction with FIGS. 14 and 15. The front side metallization layer 225 of the second die 200 is bonded 1910 to the front side metallization layer 205 of the first die 200 after the first carrier wafer 500 is repositioned to the back side 204 of the first die 200. Accordingly, in various implementations, the front side metallization layer 205 of the first die 200 is bonded 1910 to the front side metallization layer 225 of the second die 220 after the conductive portions of the through silicon vias 210 are revealed, while in other implementations, the conductive portions of the through-silicon vias 210 are revealed after the first die 200 is bonded 1910 to the front side metallization layer 225 of the second die 220.

In some implementations, the method further includes forming 1915 a back side metallization layer 215 in the first die 200, with each of the set of through-silicon vias 210 coupled to the back side metallization layer 215. For example, an end of a through silicon via 210 is coupled to the front side metallization layer 205 of the first die 200, while an opposite end of the through silicon via 210 is coupled to the back side metallization layer 205 of the first die 200. This allows the through silicon via 210 to conductively couple the front side metallization layer 215 to the back side metallization layer 205, as further described above in conjunction with FIGS. 2, 11, and 12

In some implementations, the back side metallization layer 215 is formed 1915 by removing a portion of a back side 204 of the first die 200 to reveal conductive portions of one or more of the through-silicon vias 210, as further described above in conjunction with FIG. 10. The back side 204 of the first die 200 is opposite to the front side 202 of the first die 200. In some implementations, the back side metallization layer 215 is formed 915 after revealing the conductive portions of the one or more through-silicon vias 210, with the back side metallization layer 215 coupled to the exposed conductive portions of the one or more through-silicon vias 210 of the set. In other implementations, a first carrier wafer 500 is coupled to a back side 204 of the first die 200, as shown in FIG. 5. In such implementations, the back side metallization layer 215 is formed 1915 by removing the first carrier wafer 500 from the back side 204 of the first die 200, removing a portion of the back side 204 of the first die 200 to reveal the conductive portions of the one or more through-silicon vias 210 of the set. In some implementations, a second carrier wafer 900 is coupled to a back side of the second die 220 before removing the first carrier wafer 500 from the back side 204 of the first die 200, as shown in FIG. 9. With the conductive portions of the one or more through silicon vias 210 revealed, the back side metallization layer is formed 1915 and coupled to the revelated conductive portions of the one or more through-silicon vias 210, as further described above in conjunction with FIGS. 9-12.

In view of the explanations set forth above, readers will recognize that manufacturing an integrated circuit device assembly having a front side metallization layer of a first die bonded to a front side metallization layer of the second die increases a number of interconnections between the first die and the second die. The number of interconnections between the first die and the second die is decoupled from a number of through-silicon vias in the first die when the front side metallization layer of the first die is bonded to the front side metallization layer of the second die. Such bonding of the front side metallization layer of a first die to the front side metallization layer of the second die allows more rapid scaling of a number and a density of interconnections between the first die and the second die than conventional methods where through-silicon vias in the first die establish interconnections between the first die and the second die.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

What is claimed is:

1. A semiconductor assembly comprising:
a first die having a front side metallization layer; and
a second die having a front side metallization layer bonded to the front side metallization layer of the first die.

2. The semiconductor assembly of claim 1, wherein the first die further includes a set of through-silicon vias coupled to the front side metallization layer of the first die.

3. The semiconductor assembly of claim 2, wherein the first die further includes a back side metallization layer and one or more of the through-silicon vias are coupled to the back side metallization layer.

4. The semiconductor assembly of claim 3, further comprising one or more solder bumps coupled to the back side metallization layer of the first die.

5. The semiconductor assembly of claim 2, wherein the front side metallization layer of the first die is bonded to the front side metallization layer of the second die using a hybrid bond.

6. The semiconductor assembly of claim 5, wherein a pitch of interconnections between the front side metallization layer of the first die and the front side metallization layer of the second die is different than a pitch of the through-silicon vias.

7. The semiconductor assembly of claim 1, further comprising:
an interconnect die having a metallization layer coupled to the front side metallization layer of the first die.

8. The semiconductor assembly of claim 7, wherein the metallization layer of the interconnect die is coupled to a third die that is co-planar with the first die.

9. The semiconductor assembly of claim 8, wherein the metallization layer of the interconnect die is bonded to a front size metallization layer of the third die.

10. The semiconductor assembly of claim 1, wherein a thickness of the first die is greater than a thickness of the second die.

11. The semiconductor assembly of claim 1, wherein a portion of the front side metallization layer of the second die is bonded to the front side metallization layer of the first die and another portion of the front side metallization layer of the second die is bonded to a front side metallization layer of a third die that is co-planar with the first die.

12. The semiconductor assembly of claim 1, wherein the second die is on top of the first die.

13. A method of manufacturing a semiconductor assembly comprising:
forming a set of through-silicon vias in a first die, each through-silicon via coupled to a front side metallization layer of the first die; and
bonding a front side metallization layer of a second die to the front side metallization layer of the first die.

14. The method of claim 13, further comprising:
forming a back side metallization layer in the first die, each of the set of through-silicon vias coupled to the back side metallization layer.

15. The method of claim 14, wherein forming the back side metallization layer comprises:
removing a portion of a back side of the first die to reveal conductive portions of one or more of the through-silicon vias; and
forming the back side metallization layer after revealing the conductive portions of the one or more through-silicon vias, the back side metallization layer coupled to the conductive portions of the one or more through-silicon vias of the set.

16. The method of claim 14, wherein:
a first carrier wafer is coupled to a back side of the first die; and
forming the back side metallization layer in the first die further comprises:
removing the first carrier wafer from the back side of the first die;
removing a portion of the back side of the first die to reveal conductive portions of one or more through-silicon vias of the set; and
forming the back side metallization layer after revealing the conductive portions of the one or more through-silicon vias.

17. The method of claim 16, further comprising:
coupling a second carrier wafer to a back side of the second die before removing the first carrier wafer from the back side of the first die.

18. The method of claim 13, wherein bonding the front side metallization layer of the second die to the front side metallization layer of the first die comprises:
removing a portion of a back side of the first die to reveal conductive portions of one or more through-silicon vias of the set; and
bonding the front side metallization layer of the second die to the front side metallization layer of the first die after revealing the conductive portions of the one or more through-silicon vias of the set.

19. The method of claim 13, wherein:
a first carrier wafer is coupled to a front side of the first die, and bonding the front side metallization layer of the second die to the front side metallization layer of the first die further comprises:
removing a portion of a back side of the first die to reveal conductive portions of one or more through-silicon vias of the set;
repositioning the first carrier wafer from the front side of the first die to the back side of the first die; and
bonding the front side metallization layer of the second die to the front side metallization layer of the first die after repositioning the first carrier wafer.

20. The method of claim 19, wherein repositioning the first carrier wafer from the front side of the first die to the back side of the first die comprises:
applying a gap fill material surrounding the first die; and
repositioning the first carrier wafer from the front side of the first die to the back side of the first die after applying the gap fill material.
